(19) United States
(12) Patent Application Publication
(10) Pub. No.: US 2024/0272556 A1
(43) Pub. Date: Aug. 15, 2024

(54) METAL CONTAINING PHOTORESIST DEVELOPER COMPOSITION, AND METHOD OF FORMING PATTERNS INCLUDING STEP OF DEVELOPING USING THE COMPOSITION

(71) Applicant: SAMSUNG SDI CO., LTD., Yongin-si (KR)

(72) Inventors: GyeongRyeong BAK, Suwon-si (KR); Hyungrang MOON, Suwon-si (KR); Ryunmin HEO, Suwon-si (KR); TaekSoo KWAK, Suwon-si (KR); Taegeun SEONG, Suwon-si (KR); ChungHeon LEE, Suwon-si (KR); Byeonggyu HWANG, Suwon-si (KR); Minsoo KIM, Suwon-si (KR)

(21) Appl. No.: 18/508,171

(22) Filed: Nov. 13, 2023

(30) Foreign Application Priority Data
Feb. 3, 2023 (KR) 10-2023-0015050

(51) Int. Cl. G03F 7/32; G03F 7/16

(52) U.S. Cl. CPC G03F 7/32

(57) ABSTRACT

Disclosed are a metal-containing photoresist developer composition, and a method of forming patterns including a developing step utilizing the metal-containing photoresist developer composition. The metal-containing photoresist developer composition includes an organic solvent, an acid compound having 1.0≤pKa1≤4.8, and at least one alcohol-based compound selected from a diol compound derived from an acyclic hydrocarbon and a cyclic alcohol compound.

### CROSS-REFERENCE TO RELATED APPLICATION

This application claims priority to and the benefit of Korean Patent Application No. 10-2023-0015050, filed in the Korean Intellectual Property Office on Feb. 3, 2023, the entire content of which is incorporated herein by reference.

### BACKGROUND

### 1. Field

One or more embodiments of the present disclosure relate to a metal-containing photoresist developer composition, and a method of forming patterns including a developing step (task or act) utilizing the metal-containing photoresist developer composition.

### 2. Description of the Related Art

In recent years, a continuous need or desire arise in the semiconductor industry to have a reduction of critical dimensions, and this dimensional reduction requires new types (kinds) of high-performance photoresist materials and a patterning method that can satisfy a demand for processing and patterning with increasingly smaller features.

Chemically amplified (CA) photoresists are designed to secure high sensitivity, but because an elemental makeup thereof (mainly, in smaller quantities of O, F, and S, C) lowers absorbance at a wavelength of about 13.5 nm and, as a result, reduces sensitivity, and the CA photoresists may suffer more difficulties and issues partially under the extreme ultraviolet (EUV) exposure. In addition, the CA photoresists may have difficulties and problems due to roughness issues in small feature sizes, and due partially to the nature of acid catalytic processes, LER (line edge roughness) is expected to increase as a photospeed decreases. Due to these drawbacks and problems of the CA photoresist a new type or kind of high-performance photoresists is required and highly desired in the semiconductor industry.

In particular, it is desirable to develop a photoresist securing excellent or suitable etching resistance and resolution and concurrently (e.g., simultaneously), improving sensitivity and enhancing CD (critical dimension) uniformity characteristics and reducing LER (line edge roughness) in the photolithography process.

### SUMMARY

One or more aspects of embodiments of the present disclosure are directed toward a metal-containing photoresist developer composition.

One or more aspects of embodiments of the present disclosure are directed toward a method of forming patterns including a developing step utilizing the composition.

Additional aspects will be set forth in part in the description which follows and, in part, will be apparent from the description, or may be learned by practice of the presented embodiments of the disclosure.

According to one or more embodiments, a metal-containing photoresist developer composition (e.g., for a metal-containing photoresist) includes an organic solvent, an acid compound having 1.0≤pKa1≤4.8, and at least one alcohol-based compound selected from a diol compound derived from an acyclic hydrocarbon and a cyclic alcohol compound.

In one or more embodiments, the pKa1 of the acid compound may be 1.0≤ pKa1≤4.5.

In one or more embodiments, the acid compound may be at least one of phosphoric acid, phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, 6-hydroxyhexyl phosphonic acid, decyl phosphonic acid, methylene diphosphonic acid, nitrilotrimethylene triphosphonic acid, diphenylphosphinic acid, bis(4-methoxyphenyl) phosphinic acid, phosphinic acid, bis(hydroxymethyl) phosphinic acid, phenylphosphinic acid, p-(3-aminopropyl)-p-butylphosphinic acid, chloroacetic acid, formic acid, acetic acid, or a combination thereof.

The diol compound derived from the acyclic hydrocarbon may be represented by Chemical Formula 1 or Chemical Formula 2.

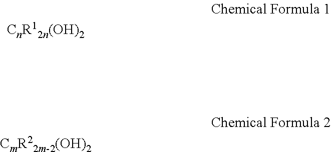

In Chemical Formula 1 and Chemical Formula 2,
R¹ and R² may each independently be hydrogen, a halogen, a substituted or unsubstituted C1 to C10 alkyl group, or a substituted or unsubstituted C6 to C20 aryl group, and n and m may each independently be an integer of greater than or equal to 2.

The cyclic alcohol compound may be represented by Chemical Formula 3 or Chemical Formula 4.

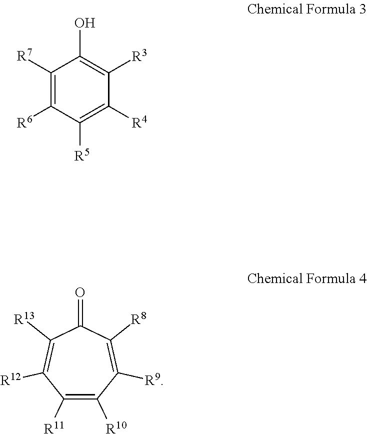

In Chemical Formula 3 and Chemical Formula 4,
R³ to R¹³ may each independently be hydrogen, a halogen, a hydroxy group, an amino group, a nitro group, a substituted or unsubstituted C1 to C30 amine group, a substituted or unsubstituted C1 to C10 alkyl group, or a substituted or unsubstituted C6 to C20 aryl group, and
at least one selected from among R⁸ to R¹³ is a hydroxy group.

In one or more embodiments, the metal-containing photoresist developer composition may include about 0.05 to about 10 wt % of the acid compound and the at least one alcohol-based compound; and a balance amount of the organic solvent (e.g., the sum of weight percentages of the acid compound, the at least one alcohol-based compound, and the organic solvent is 100 wt %).

In one or more embodiments, the acid compound and the at least one alcohol-based compound may be included in a weight ratio of about 1:0.5 to about 1:200.

In one or more embodiments, a metal-containing photoresist may include a metal compound including at least one of an organotin oxo group or an organotin carboxyl group.

In one or more embodiments, the metal compound may be represented by Chemical Formula 5.

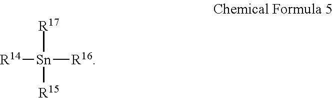

In Chemical Formula 5,
R¹⁴ may be selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl)alkyl group, and —R^{a}—O—R^{b} (wherein R^{a} is a substituted or unsubstituted C1 to C20 alkylene group and R^{b} is a substituted or unsubstituted C1 to C20 alkyl group),
R¹⁵ to R¹⁷ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl)alkyl group, —OR^{c}, or —OC(═O)R^{d},
at least one selected from among R¹⁵ to R¹⁷ may each independently be selected from —OR^{c} or —OC(═O)R^{d},
R^{c} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

In one or more embodiments, R^{c} and R^{d} may each independently be a substituted or unsubstituted C1 to C20 alkyl group.

According to one or more embodiments, a method of forming patterns includes coating a metal-containing photoresist composition on a substrate, drying and heating the resultant (e.g., the coated metal-containing photoresist composition) to form a metal-containing photoresist film on the substrate, exposing the metal-containing photoresist film, and developing the same (e.g., the exposed metal-containing photoresist film) utilizing the aforementioned metal-containing photoresist developer composition.

The metal-containing photoresist developer composition according to one or more embodiments minimizes or reduces defects present in the metal-containing photoresist film after the exposure process and enables easy development, thereby realizing excellent or suitable contrast characteristics and sensitivity, and reduced line edge roughness (LER).

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 3 are cross-sectional views illustrating a process sequence to explain a method of forming patterns according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, embodiments of the present disclosure will be described in more detail with reference to the accompanying drawings. In the following description of the present disclosure, the well-established functions or constructions will not be described in order to clarify the present disclosure.

In order to clearly illustrate the present disclosure, the unrelated description and relationships are omitted, and throughout the disclosure, the same or similar configuration elements are designated by the same reference numerals. Also, because the size and thickness of each configuration shown in the drawing are shown for better understanding and ease of description, the present disclosure is not necessarily limited thereto.

In the drawings, the thickness of layers, films, panels, regions, etc., may be exaggerated for clarity. In the drawings, the thickness of a part of layers or regions, etc., may be exaggerated for clarity. It will be understood that when an element such as a layer, film, region, or substrate is referred to as being “on” another element, it may be directly on the other element or one or more intervening elements may also be present. In contrast, when an element is referred to as being “directly on” another element, there are no intervening elements present.

In the present disclosure, “substituted” refers to replacement of a hydrogen by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” refers to that a hydrogen remains as the hydrogen without being replaced by another substituent.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. In some embodiments, the alkyl group may be a C1 to C10 alkyl group or a C1 to C6 alkyl group. For example, a C1 to C4 alkyl group refers to that the alkyl chain contains 1 to 4 carbon atoms, and may be selected from methyl, ethyl, propyl, iso-propyl, n-butyl, iso-butyl, sec-butyl, and t-butyl.

Non-limiting examples of the alkyl group may include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, etc.

In the present disclosure, the term “cycloalkyl group” refers to a monovalent cyclic aliphatic hydrocarbon group unless otherwise defined.

In the present disclosure, the term “alkenyl group”, unless otherwise defined, is a linear or branched aliphatic hydrocarbon group, and refers to an aliphatic unsaturated alkenyl group containing one or more double bonds.

In the present disclosure, the term “alkynyl group”, unless otherwise defined, is a linear or branched aliphatic hydrocarbon group, and refers to an unsaturated alkynyl group containing one or more triple bonds.

In the present disclosure, “aryl group” refers to a substituent in which all elements of a cyclic substituent have p-orbitals, and these p-orbitals form a conjugate. It may include monocyclic or fused ring polycyclic (i.e., rings that share adjacent pairs of carbon atoms) functional groups.

Hereinafter, a metal-containing photoresist developer composition according to one or more embodiments will be described in more detail.

In one or more embodiments of the present disclosure, the metal-containing photoresist developer composition may include an organic solvent, an acid compound having 1.0≤pKa1≤4.8, and at least one alcohol-based compound selected from a diol compound derived from an acyclic hydrocarbon and a cyclic alcohol compound.

In one or more embodiments, the pKa1 of the acid compound may be 1.0≤ pKa1≤4.5.

In one or more embodiments, the acid compound may be at least one of phosphoric acid, phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, 6-hydroxyhexyl phosphonic acid, decyl phosphonic acid, methylene diphosphonic acid, nitrilotrimethylene triphosphonic acid, diphenylphosphinic acid, bis(4-methoxyphenyl) phosphinic acid, phosphinic acid, bis(hydroxymethyl)phosphinic acid, phenylphosphinic acid, p-(3-aminopropyl)-p-butylphosphinic acid, chloroacetic acid, formic acid, acetic acid, or a combination thereof.

For example, in some embodiments, the acid compound may be at least one of phosphoric acid, phosphonic acid, methyl phosphonic acid, butyl phosphonic acid, phenyl phosphonic acid, vinyl phosphonic acid, chloroacetic acid, formic acid, acetic acid, or a combination thereof.

In one or more embodiments, the diol compound derived from the acyclic hydrocarbon may be a diol compound derived from a saturated hydrocarbon or an unsaturated hydrocarbon, and may be represented by Chemical Formula 1 or Chemical Formula 2.

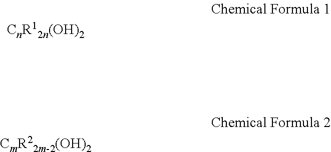

In Chemical Formula 1 and Chemical Formula 2,
R¹ and R² may each independently be hydrogen, a halogen, a substituted or unsubstituted C1 to C10 alkyl group, or a substituted or unsubstituted C6 to C20 aryl group, and
n and m may each independently be an integer of greater than or equal to 2.

For example, in some embodiments, the diol compound derived from the acyclic hydrocarbon may be 1,2-ethanediol, propylene glycol, 2-butene-2,3-diol, 2-hexene-2,3-diol, 1,2-butanediol, or a combination thereof.

In one or more embodiments, the cyclic alcohol compound may be represented by Chemical Formula 3 or Chemical Formula 4.

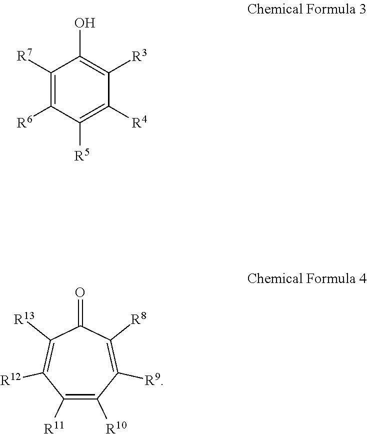

In Chemical Formula 3 and Chemical Formula 4,
R³ to R¹³ may each independently be hydrogen, a halogen, a hydroxy group, an amino group, a nitro group, a substituted or unsubstituted C1 to C30 amine group, a substituted or unsubstituted C1 to C10 alkyl group, or a substituted or unsubstituted C6 to C20 aryl group, and
at least one selected from among R⁸ to R¹³ may be a hydroxyl group.

For example, in some embodiments, at least one selected from among R³ to R⁷ may be a hydroxyl group.

In one or more embodiments, the cyclic alcohol compound may be represented by any one selected from the chemical formulas listed in Group 1.

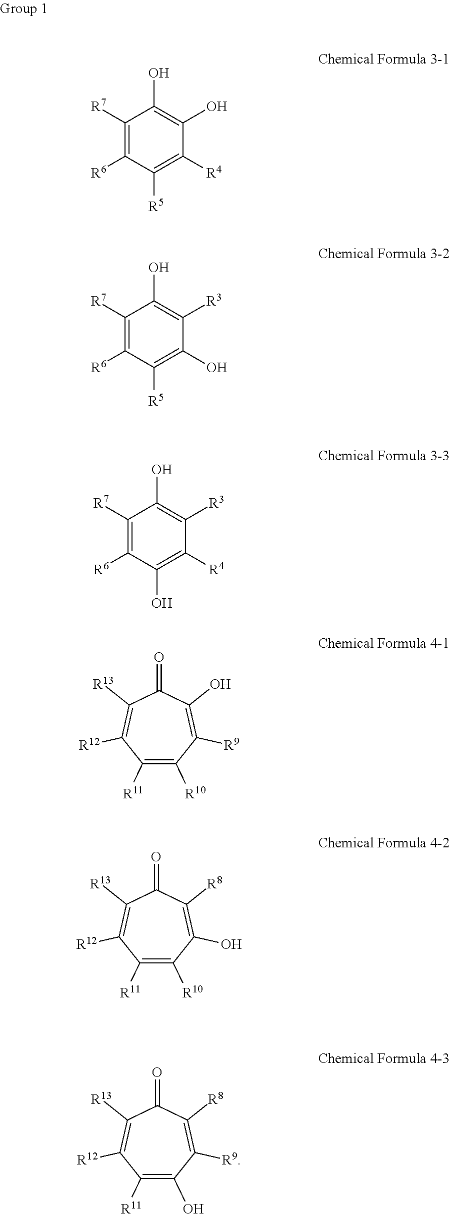

In Group 1,
R³ to R¹³ may each independently be hydrogen, a halogen, an amino group, a nitro group, a substituted or unsubstituted C1 to C30 amine group, a substituted or unsubstituted C1 to C10 alkyl group, or a substituted or unsubstituted C6 to C20 aryl group.

For example, in one or more embodiments, the cyclic alcohol compound may be selected from pyrocatechol, tropolone, and derivatives thereof listed in Group 2.

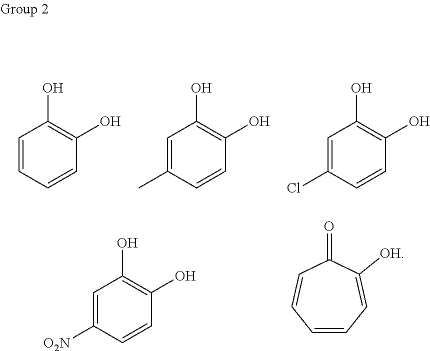

In one or more embodiments, the metal-containing photoresist developer composition may include about 0.05 to about 10 wt % of the acid compound and the at least one alcohol-based compound; and a balance amount of the organic solvent (e.g., the sum of weight percentages of the acid compound, the at least one alcohol-based compound, and the organic solvent is 100 wt %).

In one or more embodiments, the acid compound and the at least one alcohol-based compound may be included in a weight ratio of about 1:0.5 to about 1:200.

For example, in some embodiments, the acid compound and the at least one alcohol-based compound may be included in a weight ratio of about 1:1 to about 1:200, for example, about 1:1 to about 1:100.

Within the ranges, the acid compound may be included in an amount of less than about 1 wt %, specifically, less than or equal to about 0.9 wt %, and more specifically, less than or equal to about 0.8 wt %.

Within the ranges, the at least one alcohol-based compound may be included in an amount of less than about 10 wt %, less than or equal to about 9 wt %, less than or equal to about 8 wt %, or less than or equal to about 7 wt %, for example, less than or equal to about 5 wt %.

When the metal-containing photoresist developer composition including the compounds of one or more embodiments is applied, the metal-containing photoresist film may minimize or reduce defects after the exposure and may allow for easy development, thereby realizing excellent or suitable pattern characteristics.

In some embodiments, excellent or suitable sensitivity and reduced line edge roughness (LER) may also be achieved.

In one or more embodiments, the acid compound according to the present disclosure may be added to improve line edge roughness and pattern-forming capability but deteriorate pattern-forming capability due to its molecule size, but this may be compensated by adding the alcohol-based compound according to the present disclosure, thereby significantly improving pattern-forming capability.

Examples of the organic solvent included in the metal-containing photoresist developer composition according to one or more embodiments may include at least one selected from ether, alcohol, glycol ether, aromatic hydrocarbon compounds, ketone, and ester, but are not limited thereto. For example, in one or more embodiments, the organic solvent may include ethyleneglycolmonomethylether, ethyleneglycolmonoethylether, methylcellosolveacetate, ethylcellosolveacetate, diethyleneglycolmethylether, diethyleneglycolethylether, propyleneglycol, propyleneglycolmethylether (PGME), propyleneglycolmethyletheracetate (PGMEA), propyleneglycolethylether, propyleneglycolethyletheracetate, propyleneglycolpropyletheracetate, propyleneglycolbutylether, propyleneglycolbutyletheracetate, ethanol, propanol, isopropylalcohol, isobutylalcohol, 4-methyl-2-pentenol (or referred to as methyl isobutyl carbinol (MIBC)), hexanol, 1-methoxy-2-propanol, 1-ethoxy-2-propanol, ethyleneglycol, propyleneglycol, heptanone, propylenecarbonate, butylene carbonate, toluene, xylene, methylethylketone, cyclopentanone, cyclohexanone, 2-hydroxy ethyl propionate, 2-hydroxy-2-methyl ethyl propionate, ethoxy ethyl acetate, hydroxy ethyl acetate, 2-hydroxy-3-methylmethyl butanoate, 3-methoxy methyl propionate, 3-methoxy ethyl propionate, 3-ethoxy ethyl propionate, 3-ethoxy methyl propionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxyethoxy propinonate, ethoxyethoxy propinonate, or a combination thereof, but is not limited thereto.

When other additives to be described later are included, the organic solvent may be included in a balance amount except for the components (e.g., the other additives).

In one or more embodiments, the metal-containing photoresist developer composition according to the present disclosure may further include at least one selected from a surfactant, a dispersant, a moisture absorbent, and a coupling agent.

In one or more embodiments, a metal-containing photoresist may include a metal compound including at least one of an organotin oxo group or an organotin carboxyl group.

For example, in one or more embodiments, the metal compound may include a metal compound represented by Chemical Formula 5.

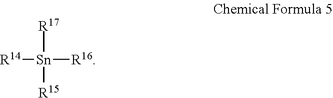

In Chemical Formula 5,
R¹⁴ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl)alkyl group, and —R^{a}—O—R^{b} (wherein R^{a} is a substituted or unsubstituted C1 to C20 alkylene group and R^{b} is a substituted or unsubstituted C1 to C20 alkyl group),
R¹⁵ to R¹⁷ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl)alkyl group, —OR^{c}, or —OC(═O)R^{d}, at least one selected from among R¹⁵ to R¹⁷ may each independently be —OR^{c} or —OC(═O)R^{d},
R^{c} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

For example, in one or more embodiments, the metal compound may include at least one of an alkyl tin oxo group or an alkyl tin carboxyl group.

For example, in some embodiments, R^{c} and R^{d} may each independently be a substituted or unsubstituted C1 to C20 alkyl group.

According to one or more embodiments, a method of forming patterns may include the step of development utilizing the aforementioned metal-containing photoresist developer composition. For example, in some embodiments, the manufactured (e.g., formed) pattern may be a negative-type or kind photoresist pattern.

In one or more embodiments, a method of forming patterns may include coating a metal-containing photoresist composition on a substrate, drying and heating the resultant (the coated metal-containing photoresist composition) to form a metal-containing photoresist film on the substrate, exposing the metal-containing photoresist film, and developing the same (e.g., the exposed metal-contained photoresist film) utilizing the aforementioned metal-containing photoresist developer composition.

In one or more embodiments, the forming of patterns utilizing the metal-containing photoresist composition may include coating a metal-containing photoresist composition on a substrate on which a thin film is formed by spin coating, slit coating, inkjet printing, etc., and drying the coated metal-containing photoresist composition to form a photoresist film. The metal-containing photoresist composition may include a tin-based compound, and for example, the tin-based compound may include at least one of an alkyl tin oxo group, an alkyl tin carboxyl group, or an alkyl tin hydroxy group.

Next, a first heat treatment process of heating the substrate on which the metal-containing photoresist film is formed is performed. The first heat treatment process may be performed at a temperature of about 80° C. to about 120° C. In this process, the solvent is evaporated and the metal-containing photoresist film may be more firmly adhered to the substrate.

And the photoresist film is selectively exposed.

For example, examples of light that may be utilized in the exposure process may include not only light having a short wavelength such as i-line (wavelength 365 nm), KrF excimer laser (wavelength of 248 nm), ArF excimer laser (wavelength of 193 nm), but also light having a high energy wavelength such as EUV (Extreme UltraViolet, wavelength of 13.5 nm), E-Beam (electron beam), etc.

In one or more embodiments, the light for exposure may be short-wavelength light having a wavelength range of about 5 nm to about 150 nm, and light having a high energy wavelength such as EUV (Extreme UltraViolet, wavelength 13.5 nm), E-Beam (electron beam), etc.

In the step (task or act) of forming the photoresist pattern, a negative-type or kind pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developer solution.

For example, in one or more embodiments, the photoresist pattern corresponding to the negative-type or kind tone image may be completed by dissolving and then removing the photoresist film corresponding to the unexposed region utilizing the aforementioned photoresist developer.

As described above, the photoresist pattern formed by exposure to not only light having a wavelength such as i-line (wavelength of 365 nm), KrF excimer laser (wavelength of 248 nm), and/or ArF excimer laser (wavelength of 193 nm), but also light having high energy such as an E-beam (electron beam) and EUV (Extreme UltraViolet; wavelength of 13.5 nm), may have a thickness width of about 5 nm to about 100 nm. For example, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern may have a pitch having a half-pitch of less than or equal to about 50 nm, for example less than or equal to about 40 nm, for example less than or equal to about 30 nm, for example less than or equal to about 20 nm, for example less than or equal to about 15 nm, and a line width roughness of less than or equal to about 10 nm, less than or equal to about 5 nm, less than or equal to about 3 nm, or less than or equal to about 2 nm.

Hereinafter, a method of forming patterns is described in more detail with reference to the drawings.

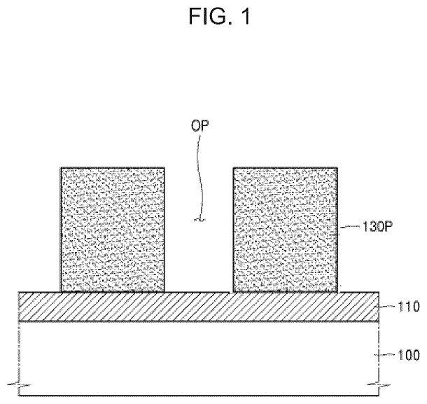

FIGS. 1 to 3 are cross-sectional views illustrating a process sequence to explain a method of forming patterns according to one or more embodiments of the present disclosure.

Referring to FIG. 1, an exposed photoresist film on a substrate 100 is developed to form a photoresist pattern 130P.

In one or more embodiments, the exposed photoresist film may be developed to remove an unexposed region of a photoresist film, and the photoresist pattern 130P including the exposed region of the photoresist film may be formed. The photoresist pattern 130P may include a plurality of openings OP.

In one or more embodiments, the development of the photoresist film may be performed through an NTD (negative-tone development) process. Herein, the metal-containing photoresist developer composition according to one or more embodiments may be utilized as a developer composition.

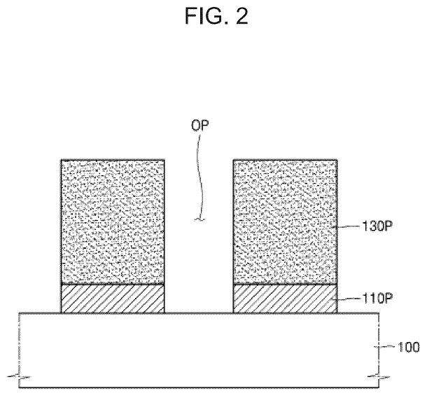

Referring to FIG. 2, the photoresist pattern 130P is utilized to process a feature layer 110 (formed) in the result of FIG. 1.

For example, the feature layer 110 may be processed through one or more suitable processes of etching the feature layer 110 exposed through the openings OP of the photoresist pattern 130P, injecting impurity ions into the feature layer 110, forming an additional film on the feature layer 110 through the openings OP, deforming a portion of the feature layer 110 through the openings OP, and/or the like. FIG. 2 illustrates an example process of processing the feature pattern 110P by etching the feature layer 110 exposed through the openings OP.

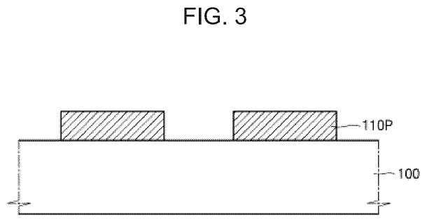

Referring to FIG. 3, the photoresist pattern 130P (formed in the result of FIG. 2 and) remaining on the feature pattern 110P is removed. In order to remove the photoresist pattern 130P, an ashing and stripping process may be utilized.

Hereinafter, the present disclosure will be described in more detail through examples relating to the preparation of the aforementioned metal-containing photoresist developer composition. However, the technical features of the present disclosure are not limited by the following examples.

### Preparation of Metal-Containing Photoresist Developer Composition

After mixing an organic solvent and additives according to compositions shown in Table in a polypropylene (PP) bottle, the additives were completely dissolved by shaking the PP bottle at room temperature (25° C.). Subsequently, each of the obtained solutions was passed through a filter formed of a PTFE material and having a pore size of 1 μm, obtaining a developer composition.

TABLE 1

| | Developer composition | | | |
|---|---|---|---|---|
| | | additive (wt %) | | |
| | Organic | Acid compound | | Alcohol-based |
| | solvent | type or kind | pKa1 | compound |
| Example 1 | PEP | methyl phosphonic acid | 2.4 | pyrocatechol |
| | | (0.1) | | (2) |
| Example 2 | MIBC | butyl phosphonic acid | 2.6 | 4-methyl catechol |
| | | (0.05) | | (5) |
| Example 3 | PGMEA | phenyl phosphonic acid | 1.8 | 4-chloro catechol |
| | | (0.03) | | (0.5) |
| Example 4 | MIBC | vinyl phosphonic acid | 2.1 | tropolone |
| | | (0.01) | | (0.1) |
| Example 5 | PGMEA | phosphoric acid | 2.2 | 4-nitro catechol |
| | | (0.5) | | (1) |
| Example 6 | PEP | butyl phosphonic acid | 2.6 | 1,2-ethanediol |
| | | (0.7) | | (5) |
| Example 7 | PGMEA | phosphonic acid | 1.3 | 4-chloro catechol |
| | | (0.5) | | (0.5) |
| Example 8 | PGMEA | chloro acetic acid | 2.9 | pyrocatechol |
| | | (0.5) | | (2) |
| Example 9 | PGMEA | formic acid | 3.8 | 4-nitro catechol |
| | | (0.8) | | (0.8) |
| Comparative | PEP | — | — | glycerol |
| Example 1 | | | | (1) |
| Comparative | PEP | butyl phosphonic acid | 2.6 | — |
| Example 2 | | (0.05) | | |
| Comparative | PGMEA | acetic acid | 4.8 | — |
| Example 3 | | (1) | | |
| Comparative | PGMEA | methyl phosphonic acid | 2.4 | isopropanol |
| Example 4 | | (0.1) | | (1) |

PEP: (=or (refers to)) PGMEA + PGME (w/w = 7:3) mixture
PGMEA: propylene glycolmethyletheracetate
PGME: propylene glycolmethylether
MIBC: methyl isobutyl carbinol

### Preparation of Metal-Containing Photoresist Composition

An organometallic compound with a structural unit represented by Chemical Formula C was dissolved in 4-methyl-2-pentanol at a concentration of 1 wt % and then, filtered with a 0.1 μm PTFE syringe filter, obtaining a metal-containing photoresist composition.

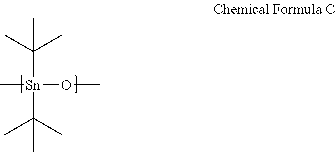

### Fabrication of Metal-containing Photoresist Patterns

On an 8 inch-silicon wafer, the photoresist composition was coated and soft-baked at 180° C. for 60 seconds. The coated wafer was exposed to light by splitting a dose with a KrF scanner made by Nikon Precision inc. The exposed wafer was immersed respectively in the developing solutions according to each of Examples 1 to 9 and Comparative Examples 1 to 4 for 30 seconds and additionally, washed with the same developer for 15 seconds to form a negative tone image, that is, to remove the unexposed coating portion. Finally, the developed wafer was baked at 240° C. on a hot plate for 60 seconds, completing the process and thus preparing a photoresist pattern.

### Evaluation 1: Measurement of Difference Between Upper and Lower Portions of Pattern

The obtained patterns were taken an image of by utilizing a field emission-scanning electron microscope (FE-SEM), the image was utilized to identify upper and lower sizes of 1:1 pattern lines, wherein the lower pattern size is divided by the upper pattern size to set a upper/lower difference, and this upper/lower difference was provided as a percentage.

### Difference Between Upper and Lower Portions

o: greater than 70%
X: less than or equal to 70%

### Evaluation 2: Evaluation of Sensitivity and Line Edge Roughness (LER)

The manufactured pattern was measured with respect to 1:1 pattern line size by utilizing a critical-dimension-scanning electron microscope (CD-SEM), and energy at a target pattern size was set as sensitivity. Herein, after measuring line edge roughness (LER) of a line at the corresponding sensitivity, the line edge roughness was evaluated into three levels according to the following criteria, and the results are shown in Table 2.

### Sensitivity

o: less than or equal to 120 mJ/cm²
X: greater than 120 mJ/cm²

### Line Edge Roughness (LER)

o: less than or equal to 2.6 nm
X: greater than 2.6 nm

TABLE 2

| | | | Difference between |
|---|---|---|---|
| | Sensitivity | LER | upper and lower portions |
| Example 1 | ◯ | ◯ | ◯ |
| Example 2 | ◯ | ◯ | ◯ |
| Example 3 | ◯ | ◯ | ◯ |
| Example 4 | ◯ | ◯ | ◯ |
| Example 5 | ◯ | ◯ | ◯ |
| Example 6 | ◯ | ◯ | ◯ |
| Example 7 | ◯ | ◯ | ◯ |
| Example 8 | ◯ | ◯ | ◯ |
| Example 9 | ◯ | ◯ | ◯ |
| Comparative Example 1 | X | X | X |
| Comparative Example 2 | X | X | ◯ |
| Comparative Example 3 | X | X | X |
| Comparative Example 4 | X | X | X |

Referring to Table 2, when the metal-containing photoresist developer compositions according to Examples 1 to 9 each are applied, compared with when the metal-containing photoresist developer compositions of Comparative Examples 1 to 4 are applied, excellent or suitable pattern characteristics, excellent or suitable sensitivity, and reduced line edge roughness were achieved.

As utilized herein, the terms “and/or” and “or” may include any and all combinations of one or more of the associated listed items. Expressions such as “at least one of,” when preceding a list of elements, modify the entire list of elements and do not modify the individual elements of the list.

It will be further understood that the terms “comprise”, “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

As utilized herein, the term “about,” or similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinbefore, the certain embodiments of the present disclosure have been described and illustrated, however, it is apparent to a person with ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

### REFERENCE NUMERALS

| | |
|---|---|
| 100: substrate | OP: opening |
| 110: feature layer | |
| 110P: feature pattern | 130P: photoresist pattern |

What is claimed is:

1. A metal-containing photoresist developer composition, comprising:
an organic solvent,
an acid compound having 1.0≤pKa1≤4.8, and
at least one alcohol-based compound selected from a diol compound derived from an acyclic hydrocarbon and a cyclic alcohol compound.

2. The metal-containing photoresist developer composition of claim 1, wherein
the pKa1 of the acid compound is 1.0≤pKa1≤4.5.

3. The metal-containing photoresist developer composition of claim 1, wherein
the acid compound is at least one of phosphoric acid, phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, 6-hydroxyhexyl phosphonic acid, decyl phosphonic acid, methylene diphosphonic acid, nitrilotrimethylene triphosphonic acid, diphenylphosphinic acid, bis(4-methoxyphenyl) phosphinic acid, phosphinic acid, bis(hydroxymethyl)phosphinic acid, phenylphosphinic acid, p-(3-aminopropyl)-p-butylphosphinic acid, chloroacetic acid, formic acid, acetic acid, or a combination thereof.

4. The metal-containing photoresist developer composition of claim 1, wherein
the diol compound derived from the acyclic hydrocarbon is represented by Chemical Formula 1 or Chemical Formula 2: 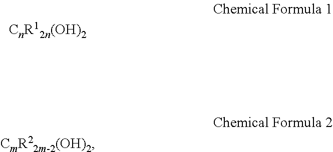
and wherein, in Chemical Formula 1 and Chemical Formula 2,
R¹ and R² are each independently hydrogen, a halogen, a substituted or unsubstituted C1 to C10 alkyl group, or a substituted or unsubstituted C6 to C20 aryl group, and
n and m are each independently an integer of greater than or equal to 2.

5. The metal-containing photoresist developer composition of claim 1, wherein
the cyclic alcohol compound is represented by Chemical Formula 3 or Chemical Formula 4: 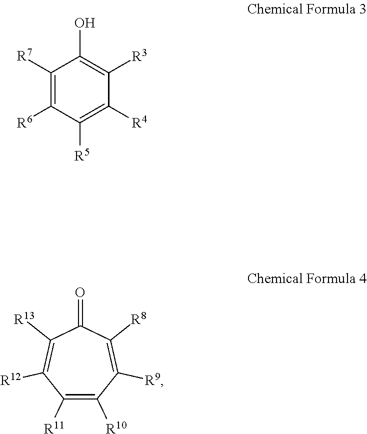
and
wherein, in Chemical Formula 3 and Chemical Formula 4,
R³ to R¹³ are each independently hydrogen, a halogen, a hydroxy group, an amino group, a nitro group, a substituted or unsubstituted C1 to C30 amine group, a substituted or unsubstituted C1 to C10 alkyl group, or a substituted or unsubstituted C6 to C20 aryl group, and
at least one selected from among R⁸ to R¹³ is a hydroxy group.

6. The metal-containing photoresist developer composition of claim 1, wherein
about 0.05 to about 10 wt % of the acid compound and the at least one alcohol-based compound; and
a balance amount of the organic solvent.

7. The metal-containing photoresist developer composition of claim 1, wherein
the acid compound and the at least one alcohol-based compound are in a weight ratio of about 1:0.5 to about 1:200.

8. The metal-containing photoresist developer composition of claim 1, wherein the metal-containing photoresist developer composition is to develop a metal-containing photoresist.

9. The metal-containing photoresist developer composition of claim 8, wherein
the metal-containing photoresist comprises a metal compound comprising at least one of an organotin oxo group or an organotin carboxyl group.

10. The metal-containing photoresist developer composition of claim 9, wherein
the metal compound is represented by Chemical Formula 5: 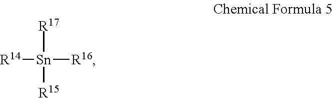
and
wherein, in Chemical Formula 5,
R¹⁴ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl)alkyl group, and —R^{a}—O—R^{b} (wherein R^{a} is a substituted or unsubstituted C1 to C20 alkylene group and R^{b} is a substituted or unsubstituted C1 to C20 alkyl group),
R¹⁵ to R¹⁷ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted (C6 to C30 aryl)alkyl group, —OR^{c}, or —OC(═O)R^{d},
at least one selected from among R¹⁵ to R¹⁷ are each independently selected from —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

11. A method of forming patterns, the method comprising
coating a metal-containing photoresist composition on a substrate;
drying and heating the coated metal-containing photoresist composition to form a metal-containing photoresist on the substrate;
exposing the metal-containing photoresist; and
developing the exposed metal-containing photoresist utilizing the metal-containing photoresist developer composition of claim 1.
